(19) United States
(12) Patent Application Publication
(10) Pub. No.: US 2025/0033076 A1
(43) Pub. Date: Jan. 30, 2025

(54) SPRAY COATER

(71) Applicant: ADRC. CO. KR, Seoul (KR)

(72) Inventor: Jin JANG, Seoul (KR)

(21) Appl. No.: 18/529,145

(22) Filed: Dec. 5, 2023

(30) Foreign Application Priority Data
Jul. 24, 2023 (KR) 10-2023-0096307

(51) Int. Cl. B05B 15/68; B05B 16/20; B05B 17/06

(52) U.S. Cl. CPC B05B 15/68; B05B 16/20; B05B 17/06

(57) ABSTRACT

Disclosed is a spray coater including a spray nozzle part including at least one ultrasonic nozzle and configured to spray a coating material, a spray nozzle mounting part including a mounting block to which the spray nozzle part is fixed, a substrate holder positioned below the spray nozzle part and configured to hold a substrate to be coated, and a controller configured to operate the spray nozzle mounting part or the substrate holder in a first scanning direction extending along one spray line, the controller being configured to control a relative position of the spray nozzle part with respect to the substrate, in which a solution material containing an oxide semiconductor precursor is injected into the spray nozzle part.

### CROSS-REFERENCE TO RELATED APPLICATION

This application claims priority to and the benefit of Korean Patent Application No. 10-2023-0096307 filed in the Korean Intellectual Property Office on Jul. 24, 2023, the entire contents of which are incorporated herein by reference.

### BACKGROUND OF THE INVENTION

### (a) Field of the Invention

The present disclosure relates to a spray coater.

### (b) Description of the Related Art

A spray coater refers to an apparatus that uses an advanced spray technology to convert a coating liquid into fine mist and apply the fine mist onto a surface of a target material. The improved function and diversity of this apparatus may be applied to a wide range of applications as well as thin-film coating on a single sheet such as photoresist coating on transparent conductive films of touch panels, solar cell components, and semiconductors.

A spray coating system has an ability to adjust a coating thickness with high precision even by using a small amount of coating liquid, and thus the spray coating system is economical and efficient. In addition, this system may consistently apply a thin film with a constant thickness to a non-uniform shape of a surface of a substrate, a surface defect, a curved shape, and various geometric shapes (quadrangular, polygonal, and cylindrical shapes) and exhibits an optimized coating result on a wide range of substrates. These characteristics allow a spray coater to be used as a very effective tool in various advanced fields.

There is a need to decrease sizes of mist particles, which is to be applied, in order to adjust a thickness of a thin film with high precision, and it is necessary to optimally maintain a reaction environment in a space in a booth during a coating process.

### SUMMARY OF THE INVENTION

The present disclosure attempts to provide a spray coater capable of spraying a coating liquid in the form of mist particles and optimally maintaining a reaction environment in a booth in which a coating process is performed.

However, the object to be achieved by the embodiments of the present disclosure is not limited to the above-mentioned object but may be variously expanded without departing from the technical spirit of the present disclosure.

An exemplary embodiment provides a spray coater including: a spray nozzle part including at least one ultrasonic nozzle and configured to spray a coating material; a spray nozzle mounting part including a mounting block to which the spray nozzle part is fixed; a substrate holder positioned below the spray nozzle part and configured to hold a substrate to be coated; and a controller configured to operate the spray nozzle mounting part or the substrate holder in a first scanning direction extending along one spray line, the controller being configured to control a relative position of the spray nozzle part with respect to the substrate, in which a solution material containing an oxide semiconductor precursor is injected into the spray nozzle part.

The spray coater may further include: a booth configured to accommodate the spray nozzle part and the substrate holder; and a gas injection part including an injection port configured to communicate with the booth, the gas injection part being configured to inject nitrogen (N₂) or oxygen (O₂).

The spray nozzle part may include a plurality of ultrasonic nozzles, and the plurality of ultrasonic nozzles may be aligned in the first scanning direction.

The spray nozzle part may include a plurality of ultrasonic nozzles, and the plurality of ultrasonic nozzles may be aligned in the second scanning direction.

The oxide semiconductor precursor may include indium (In).

The oxide semiconductor precursor may include gallium (Ga).

The oxide semiconductor precursor may include zinc (Zn).

The spray coater may further include: an ultraviolet ray emitting part configured to operate at a position above the substrate holder and emit gas molecules containing ultraviolet rays toward the substrate.

The spray coater may further include: a plasma emitting part configured to operate at a position above the substrate holder and emit gas molecules toward the substrate.

The substrate holder may include a heater provided on a portion on which the substrate is seated.

The heater may be configured to heat the substrate holder to 250° C. or higher.

The substrate holder may include a circular seating portion concavely recessed in a portion on which the substrate is seated.

The substrate holder may have a vacuum discharge port disposed adjacent to an edge of the circular seating portion.

The spray coater according to the embodiments may adopt the ultrasonic nozzle and uniformly spray the coating liquid in the form of mist particles.

In addition, the organic materials may be burnt and removed by ozone (O₃) generated by scanning the excimer ultraviolet lamp in the booth in which the coating process is performed, and nitrogen (N₂) and oxygen (O₂) gas may be supplied to optimally maintain the reaction environment.

### BRIEF DESCRIPTION OF THE DRAWINGS

FIG. 1 is a perspective view schematically illustrating a spray coater according to an embodiment.

FIGS. 2 and 3 are perspective views illustrating a modified example of the spray coater illustrated in FIG. 1.

FIG. 4 is a top plan view illustrating another modified example of the spray coater illustrated in FIG. 1.

FIG. 5 is a perspective view illustrating still another modified example of the spray coater illustrated in FIG. 1.

FIG. 6 is an image photograph illustrating a substrate holder according to the modified example of the spray coater illustrated in FIG. 1.

FIG. 7 is an image photograph illustrating a state in which a circular glass substrate is seated on the substrate holder according to the modified example of the spray coater.

FIG. 8 is a graph illustrating a result of measuring temperature distribution on the substrate holder of the spray coater illustrated in FIG. 6.

FIG. 9 is a schematic view for explaining a control system of the spray coater illustrated in FIG. 1.

FIG. 10 is a schematic view for explaining a monitor system of the spray coater illustrated in FIG. 1.

### DETAILED DESCRIPTION OF THE EMBODIMENTS

Hereinafter, embodiments of the present disclosure will be described in detail with reference to the accompanying drawings so that those with ordinary skill in the art to which the present disclosure pertains may easily carry out the embodiments. In the drawings, a part irrelevant to the description will be omitted to clearly describe the present disclosure, and the same or similar constituent elements will be designated by the same reference numerals throughout the specification. Some constituent elements in the accompanying drawings are illustrated in an exaggerated or schematic form or are omitted. A size of each constituent element does not entirely reflect an actual size.

In addition, it should be interpreted that the accompanying drawings are provided only to allow those skilled in the art to easily understand the embodiments disclosed in the present specification, and the technical spirit disclosed in the present specification is not limited by the accompanying drawings, and includes all alterations, equivalents, and alternatives that are included in the spirit and the technical scope of the present disclosure.

The terms including ordinal numbers such as “first,” “second,” and the like may be used to describe various constituent elements, but the constituent elements are not limited by the terms. These terms are used only to distinguish one constituent element from another constituent element.

In addition, when one component such as a layer, a film, an area, or a plate is described as being positioned “above” or “on” another component, one component can be positioned “directly on” another component, and one component can also be positioned on another component with other components interposed therebetween. On the contrary, when one component is described as being positioned “directly above” another component, there is no component therebetween. In addition, when a component is described as being positioned “above” or “on” a reference part, the component may be positioned “above” or “below” the reference part, and this configuration does not necessarily mean that the component is positioned “above” or “on” the reference part in a direction opposite to gravity.

Throughout the specification, it should be understood the terms “comprises,” “comprising,” “includes,” “including,” “containing,” “has,” “having” or other variations thereof are inclusive and therefore specify the presence of stated features, integers, steps, operations, elements, components, or combinations thereof, but do not preclude the presence or addition of one or more other features, integers, steps, operations, elements, components, or combinations thereof. Therefore, unless explicitly described to the contrary, the word “comprise/include” and variations such as “comprises/includes” or “comprising/including” will be understood to imply the inclusion of stated elements, not the exclusion of any other elements.

In addition, throughout the specification, the phrase “in a plan view” means when an object is viewed from above, and the phrase “in a cross-sectional view” means when a cross section made by vertically cutting an object is viewed from a lateral side.

In addition, throughout the specification, when one constituent element is referred to as being “connected to” another constituent element, one constituent element can be “directly connected to” the other constituent element, and one constituent element can also be “indirectly connected to,” “physically connected to,” or “electrically connected to” the other element with other elements therebetween. Further, the constituent elements are defined as different names according to positions or functions thereof, but the constituent elements may be integrated.

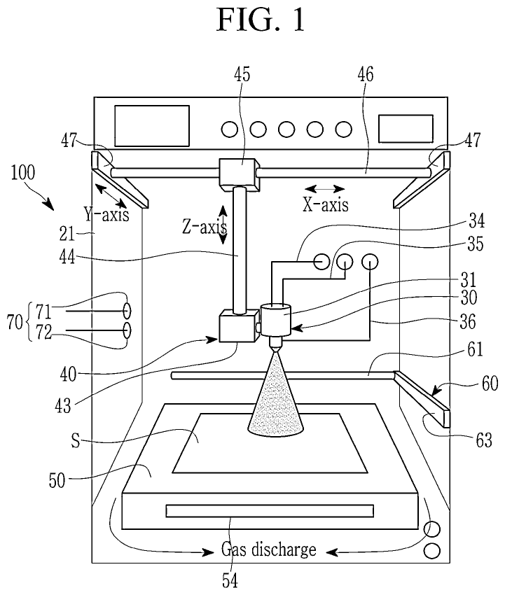

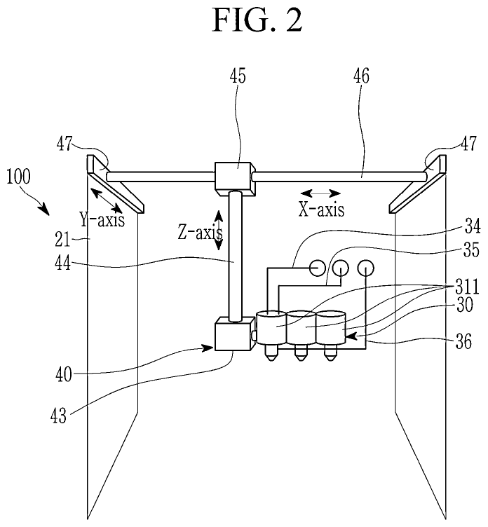

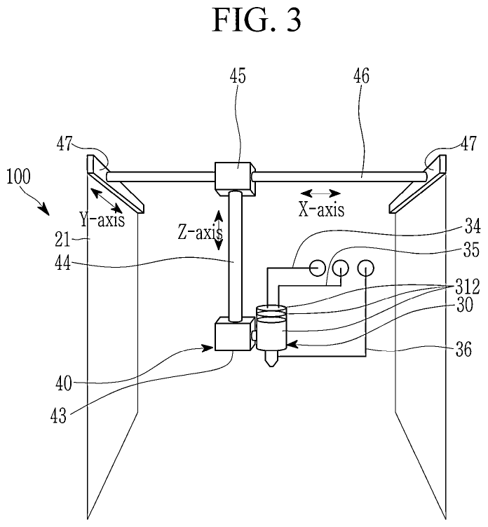

FIG. 1 is a perspective view schematically illustrating a spray coater according to an embodiment, and FIGS. 2 and 3 are perspective views illustrating a modified example of the spray coater illustrated in FIG. 1.

With reference to FIG. 1, a spray coater 100 according to the present embodiment may include a spray nozzle part 30, a spray nozzle mounting part 40, a substrate holder 50, and an ultraviolet ray emitting part 60 that are accommodated in a booth 21. A controller may control operations of these components, such that a coating process may be performed on a substrate S in the booth 21.

The spray nozzle mounting part 40 is operated by the controller in a first scanning direction, which extends along one spray line, and a second scanning direction perpendicular to the first scanning direction, such that a position of the spray nozzle part 30 relative to the substrate S may be controlled. The spray nozzle mounting part 40 may perform the coating process on the substrate S while reciprocating in a zigzag manner along a plurality of spray lines. In this case, the first scanning direction may be parallel to an x-axis direction in the drawings, and the second scanning direction may be parallel to a y-axis direction in the drawings.

As another example, the controller may control a position of the spray nozzle part 30 relative to the substrate S while operating the substrate holder 50 in the first scanning direction and the second scanning direction. This configuration also belongs to the scope of the present disclosure.

The spray nozzle part 30 may include at least one ultrasonic nozzle 31. The ultrasonic nozzle 31 may be configured to spray a coating material toward the substrate S. A coating liquid supply pipe 34, an ultrasonic generator 35, and an air supply pipe 36 may be connected to the ultrasonic nozzle 31. A coating liquid containing the coating material may be supplied through the coating liquid supply pipe 34, and air containing nitrogen N₂ may be supplied through the air supply pipe 36.

A solution material containing an oxide semiconductor precursor may be injected into the spray nozzle part 30. The oxide semiconductor precursor may include at least one of indium (In), gallium (Ga), and zinc (Zn).

The ultrasonic generator 35 may generate ultrasonic vibration on the ultrasonic nozzle 31 in accordance with a preset frequency. Therefore, the coating liquid flowing along the ultrasonic nozzle 31 may be atomized, and the atomized coating liquid may be sprayed in the form of droplets with a micro size while passing through the nozzle. The ultrasonic nozzle 31 may produce finer droplets in comparison with a cyclone type nozzle.

With reference to FIGS. 2 and 3, the spray nozzle part 30 may include a plurality of ultrasonic nozzles 311 and 312. The plurality of ultrasonic nozzles 311 and 312 may be aligned in the first scanning direction (see FIG. 2) or the second scanning direction (see FIG. 3). In the drawings, in order to simplify the illustration, the coating liquid supply pipe 34, the ultrasonic generator 35, and the air supply pipe 36 are illustrated as being connected to one of the ultrasonic nozzles 311 and 312. The coating liquid supply pipe 34, the ultrasonic generator 35, and the air supply pipe 36 may be independently connected to each of the ultrasonic nozzles 311 and 312.

The plurality of ultrasonic nozzles 311 aligned in the first scanning direction may be aligned on one spray line. In this case, in case that different types of coating liquids are supplied to the plurality of ultrasonic nozzles 311, different types of coating liquids may be sequentially coated on one spray line.

The plurality of ultrasonic nozzles 312 aligned in the second scanning direction may be disposed on the plurality of spray lines. In this case, in case that different types of coating liquids are supplied to the plurality of ultrasonic nozzles 312, different types of coating liquids may be simultaneously coated to the plurality of spray lines. In addition, in case that the same type of coating liquid is supplied to the plurality of ultrasonic nozzles 312, the spray process may be performed along the plurality of spray lines at once.

The spray nozzle mounting part 40 may include a mounting block 43, and the ultrasonic nozzle 31 of the spray nozzle part 30 may be fixed to the mounting block 43. The spray nozzle mounting part 40 may include a transfer block 45 connected by a connection shaft 44 extending in a vertical direction (a z-axis direction in the drawings) from the mounting block 43. The transfer block 45 may be coupled to the connection shaft 44 and transferred along the connection shaft 44 in the z-axis direction to adjust a distance between the spray nozzle part 30 and the substrate S.

The transfer block 45 moves a position of the mounting block 43 in a plan view while operating in the first scanning direction or the second scanning direction. To this end, the transfer block 45 may be coupled to a transfer shaft 46 extending in the first scanning direction and transferred along the transfer shaft 46. The transfer shaft 46 may operate along transfer rails 47 coupled to two opposite ends of the transfer shaft 46 and extending in the second scanning direction.

The substrate holder 50 may be positioned below the spray nozzle part 30 and configured such that the substrate S, which is a coating target, is seated on the substrate holder 50. The substrate holder 50 may include a heater 54 provided on a portion on which the substrate S is seated. The heater 54 may heat the substrate S at the time of spraying the coating liquid, thereby establishing a condition in which a thermochemical reaction occurs. The heater 54 may be configured as a hot plate.

The ultraviolet ray emitting part 60 may be positioned on an upper portion of the substrate holder 50. The ultraviolet ray emitting part 60 may operate in the first scanning direction (x-axis direction) or the second scanning direction (y-axis direction).

The ultraviolet ray emitting part 60 includes an excimer ultraviolet lamp 61 extending in one direction, and a lamp driver 63 configured to operate the excimer ultraviolet lamp 61. At least one end of the excimer ultraviolet lamp 61 may be fixed to the lamp driver 63, and the lamp driver 63 may be configured to move the excimer ultraviolet lamp 61 in a direction perpendicular to a direction in which the excimer ultraviolet lamp 61 extends. With reference to FIG. 1, the excimer ultraviolet lamp 61 may extend in the first scanning direction and be moved in the second scanning direction by the lamp driver 63. Therefore, the excimer ultraviolet lamp 61 may move to one side in the booth 21 so as not to interfere with the operation of the spray nozzle part 30.

Alternatively, a plasma emitting part may be provided instead of the ultraviolet ray emitting part 60. That is, the plasma emitting part may be substituted for the ultraviolet ray emitting part 60 and configured to emit gas molecules toward the substrate S while operating at a position above the substrate holder 50.

The spray coater 100 according to the present embodiment may include a gas injection part 70 including injection ports 71 and 72 configured to communicate with the interior of the booth 21, and the gas injection part 70 may be configured to inject nitrogen N₂ or oxygen O₂. The gas injection part 70 may provide an environment suitable for the reaction by injecting nitrogen gas and oxygen gas into the booth 21. Because nitrogen N₂ is a stable gas, the nitrogen may remove organic materials or carbon from the substrate S, thereby minimizing external contamination.

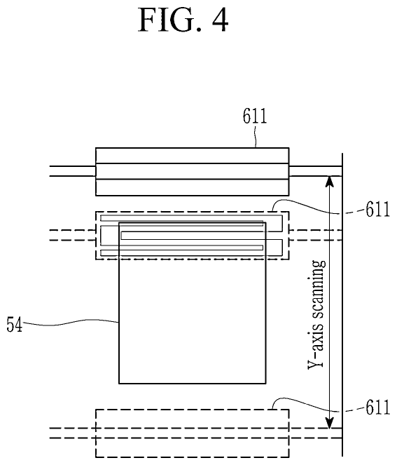

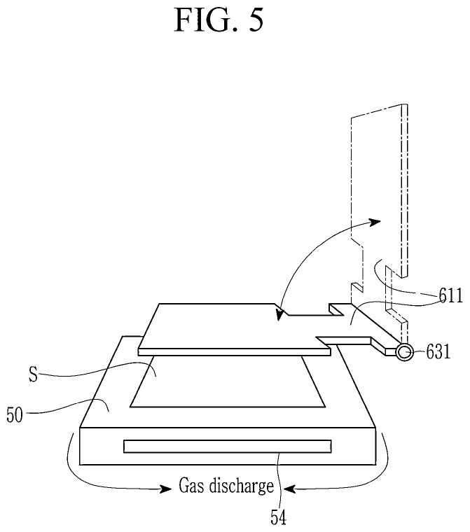

FIG. 4 is a top plan view illustrating another modified example of the spray coater illustrated in FIG. 1, and FIG. 5 is a perspective view illustrating still another modified example of the spray coater illustrated in FIG. 1.

With reference to FIG. 4, in another modified example of the spray coater 100, the spray coater 100 may include an excimer ultraviolet lamp 611 extending in a serpentine shape. The lamp extending in a serpentine shape includes a plurality of lamp portions extending in the first scanning direction, and connection portions extending in the second scanning direction and configured to alternately connect the plurality of lamp portions. The plurality of lamp portions, which are connected to one another by the connection portions, may constitute the integrated excimer ultraviolet lamp 61.

With reference to FIG. 5, in still another modified example of the spray coater 100, the ultraviolet ray emitting part 60 may include an excimer ultraviolet lamp 611 have a planar shape, and a lamp driver 631 hingedly coupled to one side edge of the excimer ultraviolet lamp 611 and configured to pivot about an axis parallel to the first scanning direction or the second scanning direction. The excimer ultraviolet lamp 61 having a planar shape may be configured by arranging a plurality of linear lamps to have an area that may cover the entire substrate S. Two opposite ends of the plurality of linear lamps are alternately connected to constitute an integrated lamp structure.

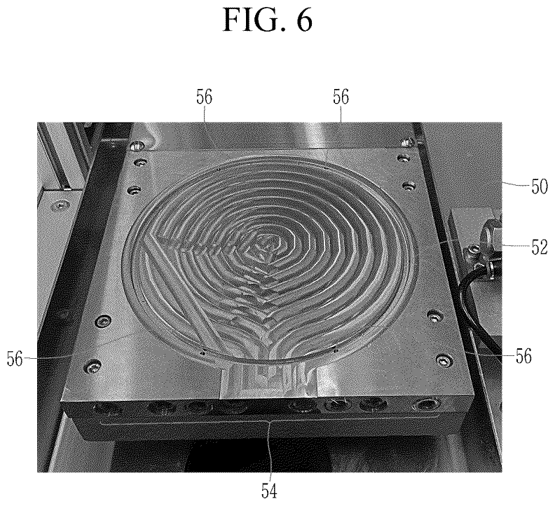

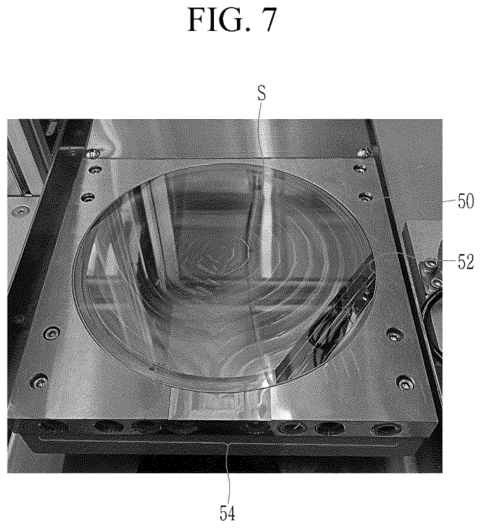

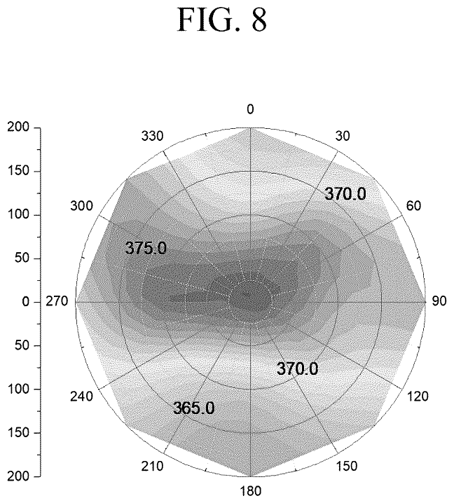

FIG. 6 is an image photograph illustrating the substrate holder according to the modified example of the spray coater illustrated in FIG. 1, FIG. 7 is an image photograph illustrating a state in which a circular glass substrate is seated on the substrate holder according to the modified example of the spray coater, and FIG. 8 is a graph illustrating a result of measuring temperature distribution on the substrate holder of the spray coater illustrated in FIG. 6.

With reference to FIG. 6, the substrate holder 50 according to the modified example includes circular seating portions 52 concavely recessed in the portion on which the substrate S is seated. The circular glass substrate S may be seated on the circular seating portions 52 (see FIG. 7). Level differences are provided along edges of the seating portions 52, such that the glass substrate S may be stably fixed.

A polygonal substrate may be seated in the circular seating portions 52 of the substrate holder 50. The polygonal substrate may be seated as edges of the polygonal substrate come into contact with the edges of the seating portions 52.

The substrate holder 50 may have vacuum discharge ports 56 disposed adjacent to the edges of the circular seating portions 52. For example, the vacuum discharge ports 56 may be four holes disposed to be spaced apart from one another. When the polygonal substrate is seated on the seating portions 52, the four vacuum discharge ports 56 may be positioned on an outer periphery of the substrate. When the substrate S is seated on the seating portions 52, the vacuum discharge ports 56 generate a vacuum suction force through the holes, such that the substrate S may be stably fixed to the substrate holder 50.

The heater 54 of the substrate holder 50 may be disposed in the circular seating portions 52. The heater 54 may be controlled to maintain uniform temperature distribution in an overall area when the substrate S is seated on the seating portions 52. To this end, the heater 54 may include a plurality of heating tubes disposed below the seating portions 52. The temperatures of the plurality of heating tubes may be independently controlled. For example, the heater 54 may be configured to heat the substrate holder 50 to 250° C. or higher.

With reference to FIG. 8 and Table 1, when a setting temperature of 400° C. is set for the substrate S having a size of 8 inches, a maximum temperature (Max) is 378° C., a minimum temperature (Min) is 363° C., and temperature uniformity (uniformity=(Max−Min)/(Max+Min)*100) is calculated as 2%.

TABLE 1

| | 8 inch |
|---|---|
| Parameters | Setting Temperature: 400° C. |
| Average | 370 |
| Max | 378 |
| Min | 363 |
| Gap | 15 |
| Uniformity (%) | 2.0% |

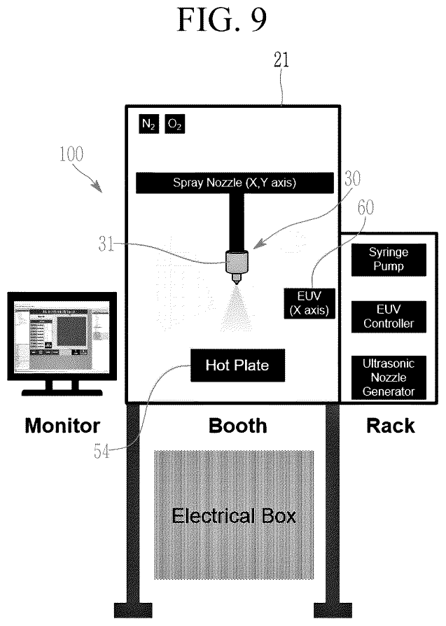

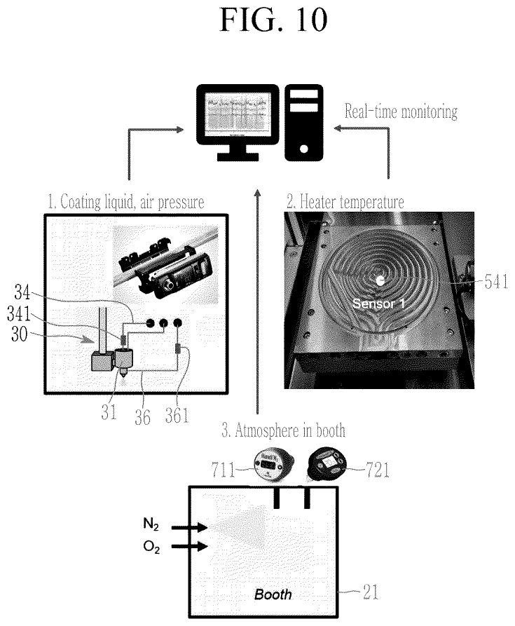

FIG. 9 is a schematic view for explaining a control system of the spray coater illustrated in FIG. 1, and FIG. 10 is a schematic view for explaining a monitor system of the spray coater illustrated in FIG. 1.

With reference to FIG. 9, in the booth 21 of the spray coater 100, the spray nozzle part 30 and the ultraviolet ray emitting part 60 may be controlled by a stepping motor, the heater (hot plate) 54 of the substrate holder 50 may be controlled by proportional-integral-differential (PID) control. A syringe pump configured to supply the coating liquid to the ultrasonic nozzle 31 of the spray nozzle part 30 may be controlled by a servo motor.

A generator frequency of the ultrasonic nozzle 31, power on/off of the ultraviolet ray emitting part 60, and a position of the spray nozzle part 30 in the vertical direction (z-axis direction) may be manually set.

In addition, the concentration of nitrogen N₂ and oxygen O₂ injected to control atmosphere in the booth 21 may be measured by an added sensor, and the pressure of nitrogen N₂ and oxygen O₂ may be controlled by a regulator.

With reference to FIG. 10, a flow rate sensor 341 may be disposed on the coating liquid supply pipe 34 to monitor a flow rate of the coating liquid supplied from the spray nozzle part 30 to the ultrasonic nozzle 31. A pressure sensor 361 may be disposed in the air supply pipe 36 to monitor pressure of air supplied to the ultrasonic nozzle 31. A temperature sensor 541 may be disposed to monitor a temperature of the heater 54 positioned in the seating portions 52 of the substrate holder 50. Concentration sensors 711 and 721 may be disposed in the booth 21 to monitor the concentration of nitrogen N₂ and oxygen injected to control the atmosphere in the booth 21. The monitoring may be performed in real time.

Meanwhile, during the process of forming an oxide thin film with a constant thickness on the substrate S by the spray coater 100 according to the present embodiment, a plasma emitting process, an ultraviolet ray emitting process, or a furnace annealing process may be additionally performed before or after the oxide thin film is deposited by applying the solution material using the spray nozzle part 30. The plasma emitting process, the ultraviolet ray emitting process, or the furnace annealing process may be repeated at least twice.

In addition, during the process of forming an oxide thin film with a constant thickness on the substrate S by the spray coater 100 according to the present embodiment, a gate insulation film may be deposited before or after the oxide thin film is deposited by applying the solution material using the spray nozzle part 30.

While the exemplary embodiments of the present disclosure have been described above, the present disclosure is not limited thereto, and various modifications can be made and carried out within the scope of the claims, the detailed description of the present disclosure, and the accompanying drawings, and also fall within the scope of the present disclosure.

What is claimed is:

1. A spray coater comprising:
a spray nozzle part including at least one ultrasonic nozzle and configured to spray a coating material;
a spray nozzle mounting part including a mounting block to which the spray nozzle part is fixed;
a substrate holder positioned below the spray nozzle part and configured to hold a substrate to be coated; and
a controller configured to operate the spray nozzle mounting part or the substrate holder in a first scanning direction extending along one spray line, the controller being configured to control a relative position of the spray nozzle part with respect to the substrate,
wherein a solution material containing an oxide semiconductor precursor is injected into the spray nozzle part.

2. The spray coater of claim 1, further comprising:
a booth configured to accommodate the spray nozzle part and the substrate holder; and
a gas injection part including an injection port configured to communicate with the booth, the gas injection part being configured to inject nitrogen (N₂) or oxygen (O₂).

3. The spray coater of claim 1, wherein:
the spray nozzle part comprises a plurality of ultrasonic nozzles, and
the plurality of ultrasonic nozzles is aligned in the first scanning direction.

4. The spray coater of claim 1, wherein:
the spray nozzle part comprises a plurality of ultrasonic nozzles, and
the plurality of ultrasonic nozzles is aligned in the second scanning direction.

5. The spray coater of claim 1, wherein:
the oxide semiconductor precursor includes indium (In).

6. The spray coater of claim 1, wherein:
the oxide semiconductor precursor includes gallium (Ga).

7. The spray coater of claim 1, wherein:
the oxide semiconductor precursor includes zinc (Zn).

8. The spray coater of claim 1, further comprising:
an ultraviolet ray emitting part configured to operate at a position above the substrate holder and emit gas molecules containing ultraviolet rays toward the substrate.

9. The spray coater of claim 1, further comprising:
a plasma emitting part configured to operate at a position above the substrate holder and emit gas molecules toward the substrate.

10. The spray coater of claim 1, wherein:
the substrate holder comprises a heater provided on a portion on which the substrate is seated.

11. The spray coater of claim 10, wherein:
the heater is configured to heat the substrate holder to 250° C. or higher.

12. The spray coater of claim 1, wherein:
the substrate holder comprises a circular seating portion concavely recessed in a portion on which the substrate is seated.

13. The spray coater of claim 12, wherein:
the substrate holder has a vacuum discharge port disposed adjacent to an edge of the circular seating portion.

14. The spray coater of claim 1, wherein:
a plasma emitting process, an ultraviolet ray emitting process, or a furnace annealing process is additionally performed before or after an oxide thin film is deposited by applying the solution material using the spray nozzle part.

15. The spray coater of claim 14, wherein:
the plasma emitting process, the ultraviolet ray emitting process, or the furnace annealing process is repeated at least twice.

16. The spray coater of claim 1, wherein:
a gate insulation film is deposited before or after an oxide thin film is deposited by applying the solution material using the spray nozzle part.
